(19) United States
(12) Patent Application Publication
(10) Pub. No.: US 2026/0029444 A1
(43) Pub. Date: Jan. 29, 2026

(54) LOAD SENSING INDICATORS FOR POWER TOOL

(71) Applicant: MILWAUKEE ELECTRIC TOOL CORPORATION, Brookfield, WI (US)

(72) Inventors: Zachary J. Jud, Milwaukee, WI (US); John R. Elwart, Menomonee Falls, WI (US); Brennan B. O’Gorman, West Bend, WI (US); Brittany A. Sellnow, Milwaukee, WI (US)

(21) Appl. No.: 19/277,761

(22) Filed: Jul. 23, 2025

Related U.S. Application Data
(60) Provisional application No. 63/675,372, filed on Jul. 25, 2024.

(51) Int. Cl. G01R 21/06; G01R 31/34

(52) U.S. Cl. CPC G01R 21/06; G01R 31/343

(57) ABSTRACT

Power tools and methods for operating the same. One power tool includes a housing, a motor positioned within the housing, a trigger, a battery pack interface, an indicator, and a controller coupled to the trigger, the motor, the battery pack interface, and the indicator. The controller is configured to provide power, from a battery pack coupled to the battery pack interface, to the motor based on a displacement of the trigger, determine a first load level based on at least one selected from a group consisting of a voltage drop of the battery pack and a rotational rate error of the motor, and determine a second load level based on a power calculation. The controller is also configured to output, via the indicator, a load representation based on the first load level and the second load level.

### RELATED APPLICATIONS

This application claims priority to U.S. Provisional Application No. 63/675,372, filed Jul. 25, 2024, the entire content of which is incorporated herein by reference.

### FIELD

Embodiments described herein generally relate to power tools and, in particular, load indicators for power tools.

### SUMMARY

Aspects described herein provide, for example, a power tool. The power tool includes a housing, a motor positioned within the housing, a trigger, a battery pack interface, an indicator (e.g., a display, a speaker, or other type of output device), and a controller. The controller is coupled to the trigger, the motor, the battery pack back, and the indicator. The controller is configured to provide power to the motor from a battery pack coupled to the battery pack interface based on a displacement of the trigger. In some embodiments, the controller is also configured to determine a voltage drop of the battery pack and control the indicator to output a representation of a load the user is putting through the power tool based on the voltage drop of the battery pack. The representation output through the indicator may vary based on one or more thresholds. For example, when the load (represented by the voltage drop) exceeds a first threshold but does not exceed a second threshold (i.e., falls within a first range defined by the first and second thresholds), a first representation may be output (e.g., one segment of a plurality of segments may be illuminated). When the load (represented by the voltage drop) exceeds both the first and second thresholds but does not exceed a third threshold (i.e., falls within a second range again defined by the second and third thresholds), a second representation may be output (e.g., two segments of the plurality of segments may be illuminated). The thresholds and associated load ranges may similarly control a color and/or brightness of the representation, an animation of the representation, etc. Also, the representation may be a visual representation, an audible representation, a tactile representation, or a combination thereof. Accordingly, the indicator informs the user of the load the user is putting through the power tool. Furthermore, using thresholds based on characteristics of the battery pack, such as a voltage drop, provides improved information (as compared to thresholds based solely on motor performance) as the user is informed of how much load the battery pack can sustain. In other words, a similar or identical load applied through the power tool when powered by two different battery packs with different characteristics may be represented differently through the indicator on the power tool. Similarly, as characteristics of a battery pack change during use, the indicator may similarly change even if the load has not changed. The user can use this information to modify operation of the power tool, such as, for example, to use a battery pack more efficiently. Similarly, the controller may use the determined load to automatically control operation of the power tool, including, for example, modifying a speed of the motor or turning off power to the motor (to stop the motor). Again, using battery pack characteristics to determine a load level, allows the controller to adapt such power tool control to the current state or type of the attached battery pack and provide improved power tool operation and performance.

In some embodiments, the controller determines a plurality of load level based on different operating characteristics (e.g., of the battery pack and/or the power tool, such as the motor) and control the indicator (and/or operation of the power tool) based on the plurality of load levels. For example, in addition to determining a load level based on a voltage drop of the battery pack, the controller may be configured to determine a load level based on a power calculation (e.g., average power). This load level may also be determined by comparing the power calculation to one or more thresholds as described with respect to the voltage drop. The load level determined based on the power calculation and the load level based on the voltage drop can be used to control the indicator. For example, the two load levels can be compared to determine which load level is highest and the highest load level can be used to control the indicator.

As an alternative to or in addition to determining a load level based on the voltage drop, in some embodiments, the controller determines a load level based on a rotational rate error of the motor (e.g., revolutions per minute (RPM) error, also referred to as RPM droop). As described above with respect to the load level determined based on voltage drop, the RPM error can be compared to a plurality of thresholds to select an appropriate load level. As also described above, the load level determined based on RPM error can be compared with a load level determined based on power and the highest of the load levels can be used to control the indicator. Also, in some embodiments, more than two load levels can be compared such that the highest load level is used to control the indicator. Alternatively or in addition, one or more load levels may be combined (e.g., averaged) and used to control the indicator. By determining multiple load levels, the indicator can be used to provide useful information to a user of the power tool (e.g., as compared to using a single load level determined based on a single operating parameter), which results in improved operation of the power tool.

For example, one embodiment described herein provides a power tool comprising a housing, a motor positioned within the housing, a trigger, a battery pack interface, an indicator, and a controller. The controller is configured to provide power, from a battery pack coupled to the battery pack interface, to the motor based on a displacement of the trigger, determine a first load level based on at least one selected from a group consisting of a voltage drop of the battery pack and a rotational rate error of the motor, and determine a second load level based on a power calculation. The controller is also configured to output, via the indicator, a load representation based on the first load level and the second load level.

Another embodiment described herein provides a method of operating a power tool. The method includes providing, with a controller included in the power tool, power from a battery pack coupled to a battery pack interface of the power tool to a motor included in the power tool, determining, with the controller, a first load level based on at least one selected from a group consisting of a voltage drop of the battery pack and a rotational rate error of the motor, and determining, with the controller, a second load level based on a power calculation. The method also includes outputting, with the controller, a load representation based on the first load level and the second load level via an indicator of the power tool.

Before any embodiments are explained in detail, it is to be understood that the embodiments are not limited in application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers” and “computing devices” described in the specification can include one or more processing units, one or more computer-readable medium modules, one or more input/output interfaces, and various connections (e.g., a system bus) connecting the components.

Other features and aspects will become apparent by consideration of the following detailed description and accompanying drawings.

### BRIEF DESCRIPTION OF THE DRAWINGS

FIG. 1 illustrates a power tool in accordance with embodiments described herein.

FIG. 2 illustrates an indicator of the power tool of FIG. 1.

FIG. 3 illustrates a block diagram of a controller of the power tool of FIG. 1 in accordance with embodiments described herein.

FIG. 4A illustrates a block diagram of a method performed by the controller of FIG. 3 based on a voltage drop of a battery pack in accordance with embodiments described herein.

FIG. 4B illustrates a block diagram of a method performed by the controller of FIG. 3 based on a rotational rate error of a motor in accordance with embodiments described herein.

FIG. 5 is a perspective view of a core drill in accordance with an embodiment of the disclosure, a tool bit is coupled to the core drill.

FIG. 6 is another perspective view of the core drill of FIG. 5 without the tool bit.

### DETAILED DESCRIPTION

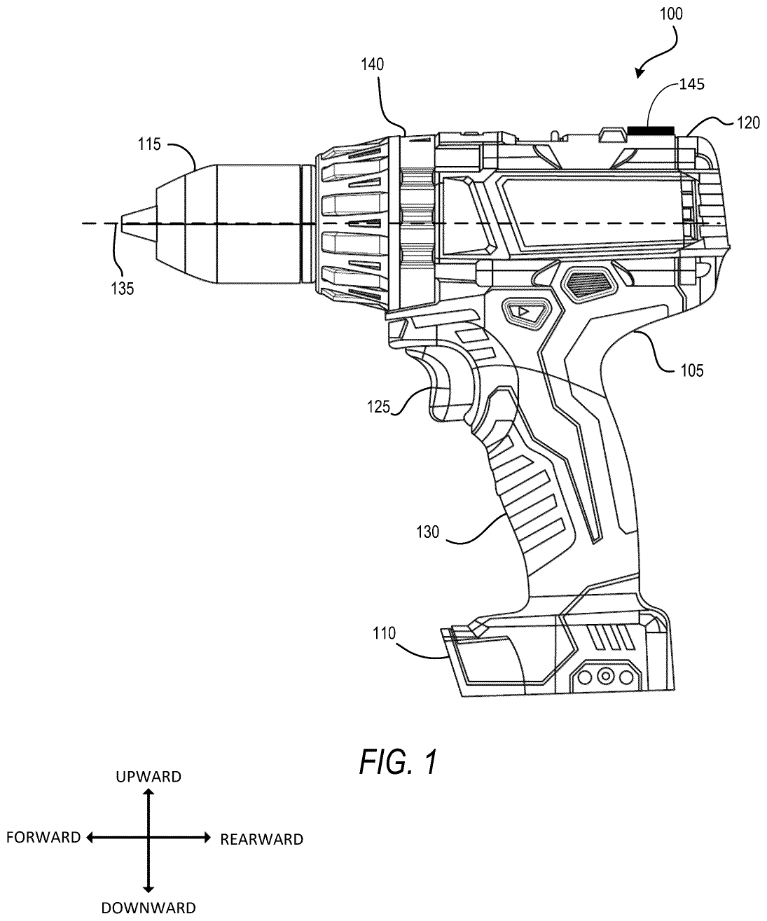

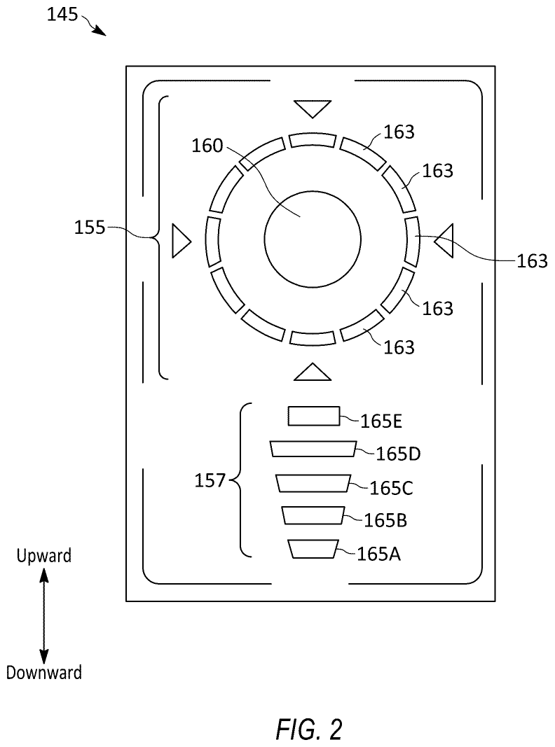

FIG. 1 illustrates an example power tool 100 according to some embodiments. The power tool 100 includes a housing 105, a battery pack interface 110, a driver 115 (e.g., a chuck or bit holder), a motor housing 120, a trigger 125, a handle 130, an input device 140, and an indicator 145 (such as a display). The motor housing 120 houses a motor 380 (see FIG. 2). A longitudinal axis 135 extends from the driver 115 through a rear of the motor housing 120. During operation, the driver 115 rotates about the longitudinal axis 135. The longitudinal axis 135 may be approximately perpendicular with the handle 130. While FIG. 1 illustrates a specific power tool 100 with a rotational output, the power tool 100 may be different type of power tool, such as various types of drills, drivers, powered screw drivers, powered ratchets, grinders, right angle drills, rotary hammers, pipe threaders, or another type of power tool that experiences rotation about an axis (e.g., the longitudinal axis 135). In some embodiments, the power tool 100 is a power tool that experiences translational movement along the longitudinal axis 135, such as reciprocal saws, chainsaws, pole-saws, circular saws, cut-off saws, die-grinder, and table saws.

As shown in FIG. 1, the indicator 145 is positioned on a top surface of the motor housing 120. In other embodiments, the indicator 145 may be positioned on a rear surface of the motor housing 120, on a surface of the housing 105 positioned above the battery pack interface 110, or on another portion of the housing 105 where the indicator 145 would be visible to a user. FIG. 2 illustrates an exemplary embodiment of the indicator 145 when the indicator 145 includes a display. In the illustrated embodiment, the indicator 145 is a liquid crystal display including a first display portion 155 and a second display portion 157. In other embodiments, the indicator 145 may be an LED display, an OLED display, an E-ink display, or a plurality of LEDs. The first and second display portions 155, 157 are each configured to graphically display one or more operational characteristics (e.g., motor speed, motor load, motor torque, battery pack capacity, tool orientation (e.g., whether the tool 100 is level), or operational mode) of the power tool 100. In other embodiments, the indicator 145 may include more or less than two display portions and may display operational characteristics of the power tool 100 numerically, as text, or a combination thereof. It should be understood that although embodiments are described herein with the indicator 145 including a display, other forms of indicators may be used in place or in addition to a display or other type of visual indicator. For example, in some embodiments, the indicator 145 includes a visual indicator, an audible indicator (e.g., a speaker), a tactical indicator (e.g., a vibrational element), or a combination thereof. In other words, the indicator 145 may include one or more output devices configured to provide feedback or information to a user of the power tool 100.

With continued reference to FIG. 2, the first display portion 155 may be configured to graphically illustrate one of the operational characteristics of the power tool 100. In the illustrated embodiment, the first display portion 155 includes a central circular segment 160 and a plurality of radial segments 163 surrounding the circular segment 160. In use, the circular segment 160 and the radial segments 163 may be configured to change brightness, color, lighting effect, or a combination thereof based on the value of one or more operational characteristics of the power tool 100. Thus, the first display portion 155 provides visual feedback to the user to, for example, inform the user of a status of the power tool 100.

With continued reference to FIG. 2, the second display portion 157 may be configured to graphically illustrate a load on the motor 380 and includes a plurality of segments 160, wherein each segment is transitionable between a plurality of states. In the illustrated embodiment, the plurality of polygonal segments 165 include 5 polygonal segments 165A-E having a different area from one another. Additionally, the polygonal segments 165 have a first state where no light is emitted by the polygonal segment 165 and a second state where a colored light is emitted from the polygonal segment 165 at a set brightness value. The colored light emitted from the polygonal segments 165 in the second state is selected from a group consisting of red, yellow, and green. In the embodiment illustrated in FIG. 2, the polygonal segments 165A, 165B selectively emit green light, the polygonal segments 165C, 165D emit yellow light, and the polygonal light 165E emits red light. In other embodiments, the polygonal segments 165 may all emit the same color of light or may emit additional colors besides red, yellow, and green. In further embodiments, the brightness of light emitted in the second state may get consistently brighter or dimmer as additional time passes, or the polygonal segments 165 may blink or pulse. In use, a number of the polygonal segments 165 will transition from the first state to the second state based on the load being put through the power tool 100, and the number of polygonal segments 165 that will transition will increase proportionally to the load as described in greater detail below.

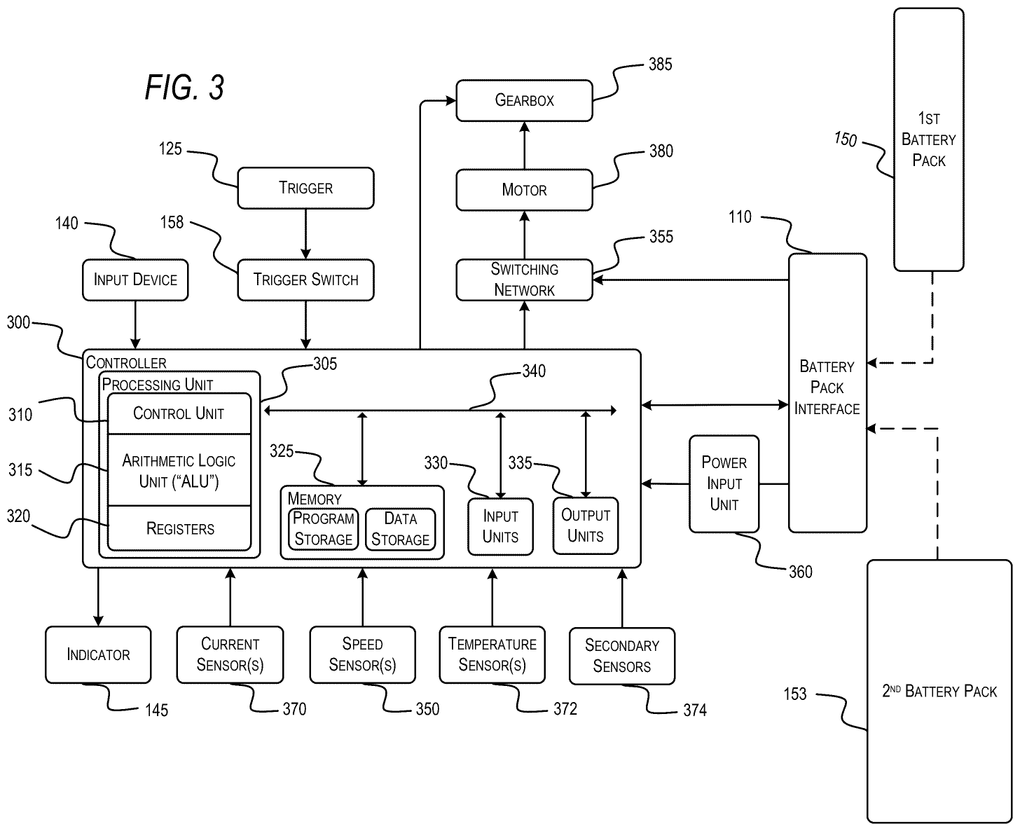

A controller 300 included in the power tool 100 is schematically illustrated in FIG. 3. The controller 300 is electrically and/or communicatively connected to a variety of modules or components of the power tool 100. For example, the illustrated controller 300 is connected to the indicator 145, a current sensor 370, a speed sensor 350, a temperature sensor 372, secondary sensor(s) 374 (e.g., a voltage sensor, an accelerometer, a torque sensor or torque transducer, etc.), the trigger 125 (via a trigger switch 158), a power switching network 355, and a power input unit 360.

The controller 300 includes a plurality of electrical and electronic components that provide power, operational control, and protection to the components and modules within the controller 300 and/or power tool 100. For example, the controller 300 includes, among other things, a processing unit 305 (e.g., a microprocessor, an electronic processor, an electronic controller, a microcontroller, or another suitable programmable device), a memory 325, input units 330, and output units 335. The processing unit 305 includes, among other things, a control unit 310, an arithmetic logic unit (“ALU”) 315, and a plurality of registers 320 (shown as a group of registers in FIG. 3) and is implemented using a known computer architecture (e.g., a modified Harvard architecture, a von Neumann architecture, etc.). The processing unit 305, the memory 325, the input units 330, and the output units 335, as well as the various modules connected to the controller 300 are connected by one or more control and/or data buses (e.g., common bus 340). The control and/or data buses are shown generally in FIG. 3 for illustrative purposes. The use of one or more control and/or data buses for the interconnection between and communication among the various modules and components would be known to a person skilled in the art in view of the embodiments described herein.

The memory 325 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 305 is connected to the memory 325 and executes software instructions that are capable of being stored in a RAM of the memory 325 (e.g., during execution), a ROM of the memory 325 (e.g., on a generally permanent basis), or another non-transitory computer readable medium such as another memory or a disc. Software included in the implementation of the power tool 100 can be stored in the memory 325 of the controller 300. The software includes, for example, firmware, one or more applications, program data, filters, rules, one or more program modules, and other executable instructions. The controller 300 is configured to retrieve from the memory 325 and execute, among other things, instructions related to the control processes and methods described herein. In other embodiments, the controller 300 includes additional, fewer, or different components.

The controller 300 drives the motor 380 to rotate the driver 115 in response to a user's actuation of the trigger 125, which may be positioned at least partially within the housing 105. The driver 115 may be coupled to the motor 380. Depression of the trigger 125 actuates a trigger switch 158, which outputs a signal to the controller 300 to drive the motor 380, and therefore the driver 115. Accordingly, the controller 300 is configured to provide power from a battery pack coupled to the battery pack interface 110 to the motor 380 based on a displacement of the trigger 125. In some embodiments, the controller 300 controls the power switching network 355 (e.g., a FET switching bridge) to drive the motor 380. For example, the power switching network 355 may include a plurality of high side switching elements (e.g., FETs) and a plurality of low side switching elements. The controller 300 may control each FET of the plurality of high side switching elements and the plurality of low side switching elements to drive each phase of the motor 380. In some embodiments, the controller 300 monitors a rotation of the motor 380 (e.g., a rotational rate of the motor 380 (e.g., revolutions per minute (RPM), a velocity of the motor 380, a position of the motor 380, and the like) via the speed sensor 350. The motor 380 may be configured to drive a gearbox 385 (e.g., a mechanism). In some implementations, the controller 300 is configured to set a gear ratio of the gears within the gearbox 385.

Separate from the indicator 145, the controller 300 may be coupled to one or more additional indicators (not shown), wherein the controller 300 can control such indicators by providing control signals to the indicators to turn on and off or otherwise convey information based on different states of the power tool 100. These indicators include, for example, one or more light-emitting diodes (LEDs), one or more displays, one or more speakers, one or more vibrational elements, or the like. These indicators can be configured to display conditions of, or information associated with, the power tool 100. For example, these indicators may display information relating to an operational state of the power tool 100, such as a mode or speed setting. Alternatively, or in addition, these indicators may provide information relating to a fault condition or other abnormality of the power tool 100. As noted with respect to the indicator 145, these indicators may include a visual indicator, a speaker, a tactile feedback mechanism, or a combination thereof to convey information to a user through visual outputs, audible outputs, tactile outputs, or a combination thereof.

The battery pack interface 110 is connected to the controller 300. As illustrated in FIG. 3, in some embodiments, the battery pack interface 110 is configured to receive (electrically couple to) a first battery pack 150 or a second battery pack 153. The first battery pack 150 and the second battery pack 153 may have different battery characteristics. For example, the first battery pack 150 may be comprised of a first number of battery cells (not shown), and the second battery pack 153 may be comprised of a second number of battery cells greater than the first number. As a result, the first battery pack 150 has a lower direct current internal resistance than the second battery pack 153. Additionally, in some embodiments, the battery pack interface 110 is configured to receive additional battery packs with the same or a different number of battery cells than the first battery pack 150 and the second battery pack 153. The battery pack interface 110 includes a combination of mechanical (e.g., a battery pack receiving portion) and electrical components configured to and operable for interfacing (e.g., mechanically, electrically, and communicatively connecting) the power tool 100 with a battery pack, such as for example, the first battery pack 150 and the second battery pack 153 (e.g., where the battery pack interface 110 can be coupled to at most one of these packs at a time but is configured to selectively receive either type of battery pack). The battery pack interface 110 is coupled to the power input unit 360. The battery pack interface 110 transmits the power received from a coupled battery pack to the power input unit 360. The power input unit 360 includes active and/or passive components (e.g., voltage step-down controllers, voltage converters, rectifiers, filters, etc.) to regulate or control the power received through the battery pack interface 110 and to the controller 300. In some embodiments, the battery pack interface 110 is also coupled to the power switching network 355. The operation of the power switching network 355, as controlled by the controller 300, determines how power is supplied to the motor 380.

The current sensor 370 senses a current provided by the battery pack 150, a current associated with the motor 380, or a combination thereof. In some embodiments, the current sensor 370 senses at least one of the phase currents of the motor 380. The current sensor 370 may be, for example, an inline phase current sensor, a pulse-width-modulation-center-sampled inverter bus current sensor, or the like. The speed sensor 350 senses a speed of the motor 380. The speed sensor 350 may include, for example, one or more Hall effect sensors. In some embodiments, the temperature sensor 372 senses a temperature of the switching network 355, the battery pack 150, the motor 380, the gearbox 385, or a combination thereof.

The input device 140 is operably coupled to the controller 300 to, for example, select a forward mode of operation, a reverse mode of operation, a torque setting for the power tool 100, a gear ratio of the gearbox 385, and/or a speed setting for the power tool 100 (e.g., using torque and/or speed switches), etc. In some embodiments, the input device 140 includes a combination of digital and analog input or output devices required to achieve a desired level of operation for the power tool 100, such as one or more knobs, one or more dials, one or more switches, one or more buttons, etc. In other embodiments, the input device 140 is configured as a ring (e.g., a torque ring). Movement of the input device 140 sets a desired torque and/or desired a speed value at which to drive the motor 380.

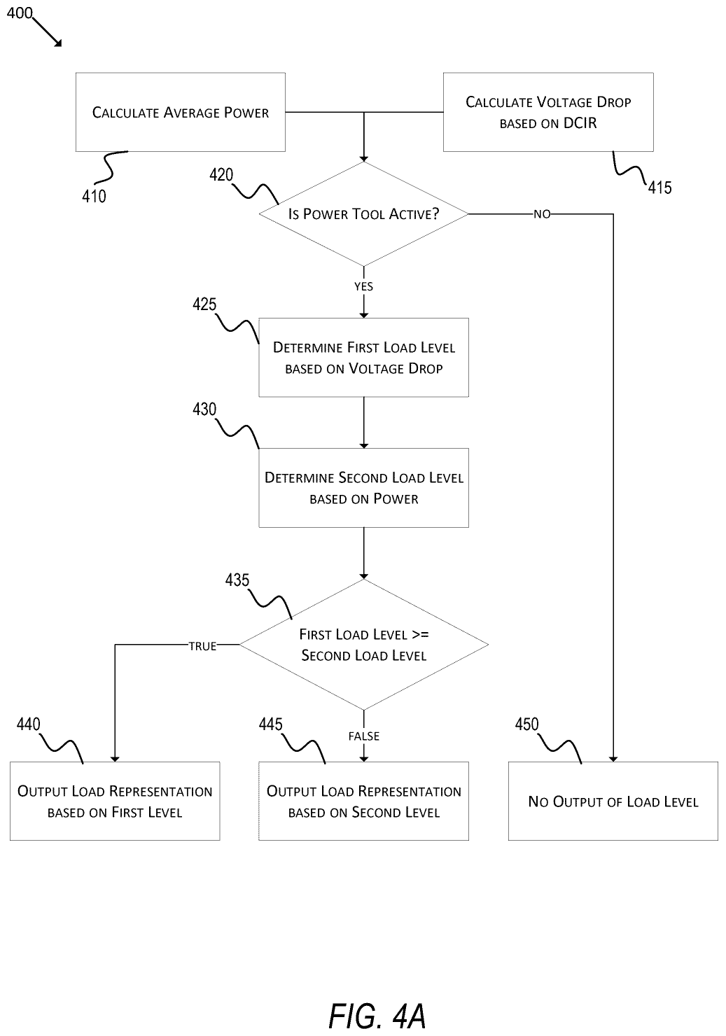

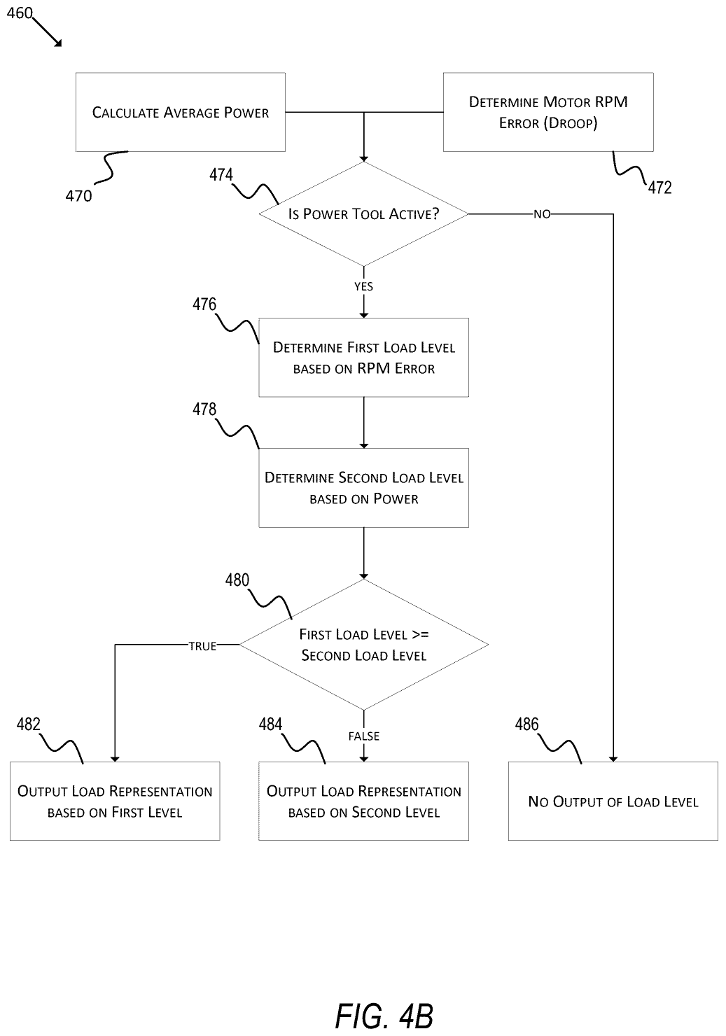

FIG. 4A is a flow chart illustrating a method 400 for outputting a load representation (representing a level of load being put through the power tool 100) via the indicator 145. As described below, the load represented via the representation can be based on either a power calculation (e.g., average power) or a voltage drop across the battery pack coupled to the interface 110 (e.g., referred to herein as an “installed battery pack”) determined using an estimated direct current internal resistance. The method 400 is described herein as being performed by the controller 300. However, it should be understood that the functionality described as part of method 400 may be distributed among a plurality of controllers in various combinations and distributions.

As illustrated in FIG. 4A, the method 400 includes the controller 300 calculating a power calculation, which may be an average power calculation (e.g., of the motor) (at block 410). To calculate average power (in watts), the controller 300 multiples an average current value by an average voltage value. The controller 300 may determine the average current value and/or the average voltage value (e.g., based on current and/or voltage measurements the controller 300 obtains from one or more sensors over a period of time). Alternatively, the controller 300 may obtain the average current value and/or the average voltage value as determined by another controller or module included in the power tool 100. Furthermore, in some embodiments, the controller 300 may obtain the power calculation from another controller or module included in the power tool 100. In some embodiments, the voltage and/or current measurements used in the power calculation may be measured (e.g., via one or more sensors) at a printed circuit board included in the controller 300. In some embodiments, the controller 300 stores the calculated average power in the memory 325.

With continued reference to FIG. 4A, the method 400 also includes calculating a voltage drop across the installed battery pack using an estimated direct current internal resistance (DCIR) value of the battery pack (at block 415), which may be directly related to the number of battery cells in the battery pack. For example, battery pack impedance (DCIR) and current can be used to estimate the voltage drop across the battery pack and this value may be determined by the controller 300 (or other controllers included in the power tool) for various power tool control or optimization functions) and, thus, also used as part of the load representation output function.

To calculate the estimated DCIR value, the controller 300 (e.g., a state of charge estimator) may use a passive technique to guess the DCIR based on bus voltage and bus current. For example, as the power tool 100 is being used, the controller 300 obtains regular voltage and current measurements over a period of time and determines maximum and minimum values at various points, which are used to calculate an estimated DCIR.

For example, the controller 300 receives (or calculates as described in the previous paragraph) a maximum and a minimum voltage (e.g., based on measurements from one of the sensors included in the secondary sensors 374, which may measure bus voltage) and a maximum and a minimum current (e.g., based on measurements of a bus current). With the received minimum and maximum current and voltage values, the controller 300 determines the estimated DCIR value, as shown in Equation 1:

$$D C I {R}_{estimate} = \frac{{V}_{max} - {V}_{min}}{{I}_{max} - {I}_{min}} \qquad [ Equation 1 ]$$

After estimating the DCIR value, the controller 300 multiples the estimated DCIR value by a current value from the current sensor 370 (representing a present or currently-sensed current value as compared to a maximum or minimum current value) to determine a voltage drop across the installed battery pack (e.g., the first battery pack 150 or the second battery pack 153). The controller 300 may also store the determined voltage drop in the memory 325.

It should be understood that other ways of measuring a voltage drop of an installed battery pack may be used in the method 400. For example, in some embodiments, the installed battery pack may communicate information to the controller 300, such as, for example, a number of cells, an internal resistance, or the like, which the controller 300 may use to determine the voltage drop. Similarly, in some embodiments, the controller 300 may receive the voltage drop value from another component or module of the power tool 100, including, for example, as determined by a controller of the installed battery pack.

With continued reference to FIG. 4A, the controller 300 checks if the power tool 100 is active (at block 420). The controller 300 may determine if the power tool 100 is active by determining whether the motor is spinning, which may include receiving a speed reading and comparing the speed reading to a speed threshold (e.g., stored in memory 325). In some embodiments, the speed sensor 350 is a hall effect sensor, which transitions from low to high or high to low based on proximity to a north or south pole of a magnet positioned on the motor shaft. The greater the number of transitions between low and high in a time period the greater the motor speed. If the controller 300 reads no transitions between low and high within a predetermined period of time (e.g., 50 microseconds), the controller 300 determines that the motor speed falls below the speed threshold. If at least one transition between low and high occurs in a 50-microsecond period, the controller 300 determine that the motor speed exceeds the speed threshold. In other embodiments, a time period greater or less than 50 microseconds may be used to determine if motor speed exceeds the speed threshold.

If the speed reading is above the speed threshold, the controller 300 may determine that the motor 380 is spinning and the method 400 proceeds to block 425. If the speed reading is below the speed threshold, the controller 300 may determine that the motor 380 is not spinning (is stationary) and the method 400 proceeds to block 450 (where no load representation is output via the indicator 145). For example, with respect to the embodiment illustrated in FIGS. 1-2, when the power tool 100 is not active, the polygonal segments 165 either remain in the first state or transition from the second state to the first state.

In other embodiments, the controller 300 may determine if the power tool 100 is active based on a reading from the trigger switch 158. If the trigger reading exceeds a trigger position threshold (e.g., stored in memory 325), the controller 300 determines that the trigger 125 is depressed and the power tool 100 is active. In further embodiments, the controller 300 may determine if the power tool 100 is active based on a current reading from the current sensor 370. If the current reading is greater than a current threshold (e.g., stored in memory 325), the controller 300 determines that the power tool 100 is active. It should be understood that the controller 300 may use other ways of determining whether the power tool 100 (e.g., the motor 380) is active. As described below, in some embodiments, the load representation is only output via the indicator 145 when the power tool 100 is active. Accordingly, in some embodiments, the controller 300 determines whether the power tool 100 is active as a perquisite for the method 400. For example, in some embodiments, the controller 300 performs block 420 to determine whether blocks 410 and 415 should be performed to avoid these blocks and other blocks (blocks 425, 430, 435, 440, and 445) of the method 400 when the power tool 100 is not active.

With continued reference to FIG. 4A, at block 425, the controller 300 determines a first load level based on the determined voltage drop value. In some embodiments, the controller 300 determines the first load level by comparing the determined voltage drop value to one or more thresholds (e.g., voltage thresholds), wherein each voltage threshold may be associated with one of a plurality of load levels. In the embodiment illustrated in FIGS. 1-2, the number of voltage thresholds may be equal to the number of segments 165. However, in other embodiments, the number of thresholds may vary and may not depend on the number of segments. The controller may determine the highest voltage threshold that the determined voltage drop value exceeds (e.g., the number of thresholds that the voltage drop value exceeds, which may specify where the determined voltage drop value falls between two thresholds) and set the load level based on the highest exceeded threshold.

For example, if there are five voltage thresholds, each threshold may be associated with a different load level, such as, for example, where a first (lowest) threshold is associated with a load level 1 and a fifth (highest) threshold is associated with a load level 5. Accordingly, if the determined voltage drop value exceeds the third threshold but not the fourth threshold, in this example, the first load level may be set to 3. In some embodiments, the controller 300 performs these threshold comparisons starting at the highest threshold and moving down thresholds until a threshold that the determined voltage drop value exceeds. The controller 300 may store the first load level in the memory 325.

With continued reference to FIG. 4A, at block 430, the controller 300 determines a second load level based on the determined power value. The controller 300 may similarly compare the average power calculated at block 410 to a plurality of power thresholds (e.g., stored in memory 325). For example, for the embodiment of the power tool 100 illustrated in FIGS. 1 and 2, the number of power thresholds may be equivalent to the number of polygonal segments 165. In other embodiments, however, the number of power thresholds may vary and may be independent of the number of segments 165. Similar to the voltage thresholds, the controller 300 may determine the second load level by determining the highest power threshold that the determined average power exceeds and set the second load level to a load level associated with the applicable power threshold. The controller 300 may store the determined second load level in the memory 325.

With continued reference to FIG. 4A, at block 435, the controller 300 compares the first load level, calculated at block 425, and the second load level, calculated at block 430, to determine, for example, which load level is highest (i.e., a highest load level) (at block 435) and outputs a load representation based on the highest load level. For example, as illustrated in FIG. 4A, in response to the first load level being higher than (or equal to) the second load level, the method 400 proceeds to block 440 where the load representation is output based on the first load level. Alternatively, in response to the second level being higher than the first load level, the method proceeds to block 445 where the load representation is output based on the second load level.

To output the load representation (at block 440 or 445), the controller 300 controls the indicator 145 (e.g., by transmitting one or more control signals) to output the appropriate representation. For example, for the embodiment illustrated in FIGS. 1-2, the representation may be output by transitioning at least a subset of the polygonal segments 165 from the first state to the second state. In some embodiments, the polygonal segments 165 will be illuminated in order from bottom to top. For instance, when the load representation is based on a load level 3 using the embodiment illustrated in FIGS. 1-2, the polygonal segments 165A, 165B, and 165C are illuminated. It should be understood that the controller 300 may repeat the method 400 (e.g., continuously or at a predetermined frequency) continue to monitor power and voltage drop and adjust the outputted load representation accordingly.

Accordingly, as described above, the power calculation is compared to a predetermined set of thresholds which may correspond to the number of segments of the indicator 145 that should be illuminated. Similarly, the estimated DCIR voltage drop is compared to a similar number of pre-determined thresholds. Both of these comparisons result in identifying a load level that corresponds to particular representation to output (e.g., a number of segments to illuminate). Depending on the magnitude of the voltage drop, determined load levels and, consequently, the determined representation (e.g., number of segments) may differ for both of these comparisons. Accordingly, the determined load levels are compared to select the highest determined load level and associated representation (e.g., highest number of segments), which is output via the indicator 145. Using both power and battery characteristics (e.g., voltage drop, which may represent an impedance of a battery pack) allows the load representation output to the user to take into consideration the battery pack type and status and provide more useful feedback. For example, when the user places a low impedance pack (e.g., 12.0 Ah) on the power tool and the estimated DCIR voltage drop is minimal, a load level of 1 may be output. However, when the user is applying enough force that the power calculation indicates a load level of 4 (i.e., 4 segments), a load level of 4 may be output. In contrast, when a user places a high impedance battery pack (e.g., 5.0 Ah) on the tool and there is a large estimated DCIR voltage drop, the same functionality applied by the controller 300 would, based on the voltage drop, determine a load level of 5 while the power-based calculation determines a load level of 2. In this situation, the load representation output to the user represents the load level 5, since that level is higher than the power-based load level of 2.

FIG. 4B is another flow chart illustrating a method 460 for outputting a load representation (representing a level of load being put through the power tool 100) via the indicator 145, which may be performed by the power tool in place of the method 400 or in combination with the method 400 (e.g., by averaging or otherwise combining the output of each method). In contrast with using voltage drop at the battery to represent a load via the indicator 145, the method 460 uses rotational rate error, such as, for example, RPM droop represented by a variable tracking a difference between a target RPM and an actual RPM. Using a rotational rate error such as RPM droop allows the controller 300 to assess when the power tool 100 is being pushed too hard by the user even when the power tool 100 is being powered by high impedance battery pack (e.g., 5.0 Ah). Similar to the method 400, the method 460 is described herein as being performed by the controller 300. However, it should be understood that the functionality described as part of method 460 may be distributed among a plurality of controllers in various combinations and distributions.

As illustrated in FIG. 4B, the method 460 includes the controller 300 calculating a power calculation, which may be an average power calculation (e.g., of the motor) (at block 470) and may be calculated as described above with respect to method 400. The method 460 also includes determining a rotational rate error of the motor 380, such as, for example, a motor RPM error (droop), which as noted above, may be calculated by subtracting an actual RPM value of the motor (as detected by one or more sensors, such as the speed sensor 350 and/or one or more of the secondary sensors 374) from a target RPM value of the motor (e.g., as set by the controller 300 or one or more other controllers included in the power tool 100 based on, for example, user input through the trigger 125 and/or input device 140) (at block 472). For example, in some embodiments, the controller 300 stores a target RPM value in the memory 325, which may be set based on, among other things, input received via the trigger 125 and/or the input device 140 (e.g., selecting an operating mode of the power tool 100). Thus, the controller 300 determines the motor RPM error by subtracting an actual motor RPM, as detected, for example, via the speed sensor 350), from the target motor RPM.

With continued reference to FIG. 4B, the controller 300 checks if the power tool 100 is active (at block 474), which the controller 300 may check as described above with respect to method 400. If the speed reading is above the speed threshold, the controller 300 may determine that the motor 380 is spinning and the method 460 proceeds to block 476. If the speed reading is below the speed threshold, the controller 300 may determine that the motor 380 is not spinning (is stationary) and the method 460 proceeds to block 486 (where no load representation is output via the indicator 145). For example, with respect to the embodiment illustrated in FIGS. 1-2, when the power tool 100 is not active, the polygonal segments 165 either remain in the first state or transition from the second state to the first state. In other embodiments, the controller 300 may determine if the power tool 100 is active (at block 474) based on a reading from the trigger switch 158. If the trigger reading exceeds a trigger position threshold (e.g., stored in memory 325), the controller 300 determines that the trigger 125 is depressed and the power tool 100 is active. In further embodiments, the controller 300 may determine if the power tool 100 is active (at block 474) based on a current reading from the current sensor 370. If the current reading is greater than a current threshold (e.g., stored in memory 325), the controller 300 determines that the power tool 100 is active. It should be understood that the controller 300 may use other ways of determining whether the power tool 100 (e.g., the motor 380) is active. As described below, in some embodiments, the load representation is only output via the indicator 145 when the power tool 100 is active. Accordingly, in some embodiments, the controller 300 determines whether the power tool 100 is active as a perquisite for the method 460. For example, in some embodiments, the controller 300 performs block 474 to determine whether blocks 470 and 472 should be performed to avoid these blocks and other blocks of the method 460 when the power tool 100 is not active.

With continued reference to FIG. 4B, at block 476, the controller 300 determines a first load level based on the determined RPM error. In some embodiments, the controller 300 determines the first load level by comparing the determined RPM error to one or more thresholds (e.g., RPM error thresholds), wherein each RPM error threshold may be associated with one of a plurality of load levels. In the embodiment illustrated in FIGS. 1-2, the number of RPM error thresholds may be equal to the number of segments 165. However, in other embodiments, the number of RPM error thresholds may vary and may not depend on the number of segments. The controller 300 may determine the highest RPM error threshold that the determined RPM error value exceeds (e.g., the number of thresholds that the RPM error value exceeds, which may specify where the determined RPM error falls between two thresholds) and set the load level based on the highest exceeded RPM error threshold.

For example, if there are five RPM error thresholds, each threshold may be associated with a different load level, such as, for example, where a first (lowest) threshold is associated with a load level 1 and a fifth (highest) threshold is associated with a load level 5. Accordingly, if the determined RPM error value exceeds the third threshold but not the fourth threshold, in this example, the first load level may be set to 3. In some embodiments, the controller 300 performs these threshold comparisons starting at the highest threshold and moving down thresholds until a threshold is identified that the determined RPM error value exceeds. The controller 300 may store the first load level in the memory 325.

With continued reference to FIG. 4B, at block 478, the controller 300 determines a second load level based on the determined power value. The controller 300 may similarly compare the average power calculated at block 470 to a plurality of power thresholds (e.g., stored in memory 325). For example, for the embodiment of the power tool 100 illustrated in FIGS. 1 and 2, the number of power thresholds may be equivalent to the number of polygonal segments 165. In other embodiments, however, the number of power thresholds may vary and may be independent of the number of segments 165. Similar to the RPM error thresholds, the controller 300 may determine the second load level by determining the highest power threshold that the determined average power exceeds and set the second load level to a load level associated with the applicable power threshold. The controller 300 may store the determined second load level in the memory 325.

With continued reference to FIG. 4B, at block 480, the controller 300 compares the first load level, calculated at block 476, and the second load level, calculated at block 478, to determine, for example, the highest load level (at block 480), which the controller 300 uses to output a load representation via the indicator 145. For example, in response to the first load level being higher than (or equal to) the second load level, the method 460 proceeds to block 482 where the load representation is output based on the first load level. Alternatively, in response to the second level being higher than the first load level, the method 460 proceeds to block 484 where the load representation is output based on the second load level.

As described above with respect to the method 400, to output the load representation (at block 482 or 484), the controller 300 controls the indicator 145 (e.g., by transmitting one or more control signals) to output the appropriate representation. For example, for the embodiment illustrated in FIGS. 1-2, the representation may be output by transitioning at least a subset of the polygonal segments 165 from the first state to the second state. In some embodiments, the polygonal segments 165 will be illuminated in order from bottom to top. For instance, when the load representation is based on a load level 3 using the embodiment illustrated in FIGS. 1-2, the polygonal segments 165A, 165B, and 165C are illuminated. It should be understood that the controller 300 may repeat the method 460 (e.g., continuously or at a predetermined frequency) continue to monitor power and RPM error and adjust the outputted load representation accordingly.

Accordingly, as described above with respect to the method 460, the power calculation is compared to a predetermined set of thresholds which may correspond to the number of segments of the indicator 145 that should be illuminated. Similarly, the RPM error is compared to a similar number of pre-determined thresholds. Both of these comparisons result in identifying a load level that corresponds to particular representation to output (e.g., a number of segments to illuminate). Depending on the magnitude of the RPM error, determined load levels and, consequently, the determined representation (e.g., number of segments) may differ for both of these comparisons. Accordingly, the determined load levels are compared to select the highest determined load level and the associated representation (e.g., highest number of segments), which is output via the indicator 145. Using both power and motor characteristics allows the load representation output to the user to take into consideration the battery pack type and status as well as motor performance and provide more useful feedback.

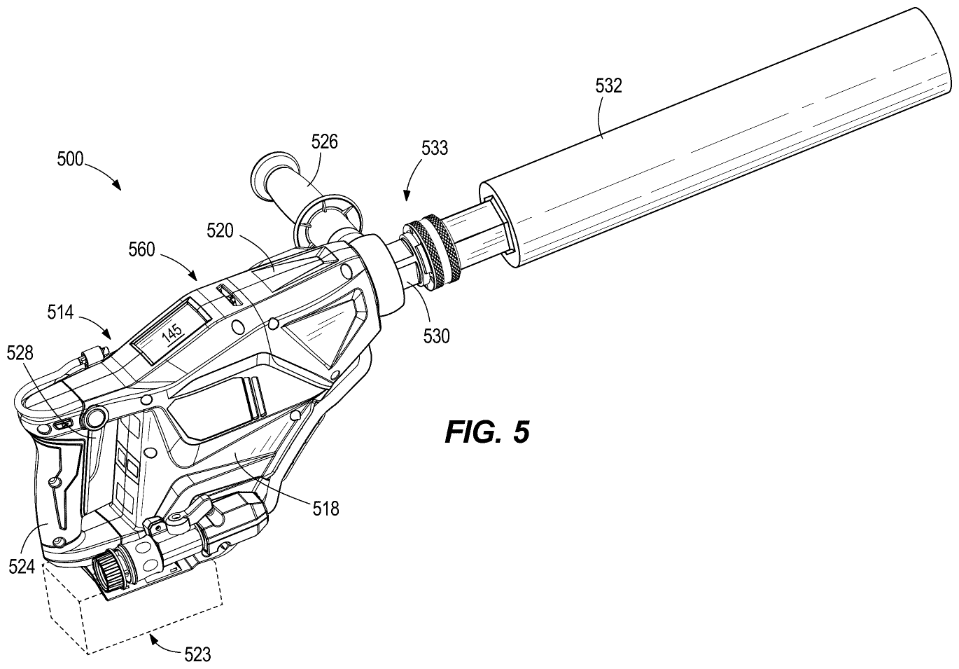

As noted above, the power tool 100 illustrated in FIG. 1 is one example of a power tool that can be used with the indicator 145 and associated functionality described herein, and embodiments described herein can be used with various types of tools. For example, FIG. 5 illustrates a power tool usable with embodiments described herein in the form of a core drill 500. The core drill 500 includes a housing 514 having a motor housing portion 518 and a drive housing portion 520. A motor (not shown) is disposed within the motor housing portion 518 of the housing 514 and is a brushless direct current motor in the illustrated embodiment. In other embodiments, the core drill 500 may include other types of motors. The illustrated core drill 500 is cordless and includes a battery 523 that provides power to the motor. In other embodiments, the core drill 500 may be a corded tool configured to receive power from a wall outlet or other remote power source.

The core drill 500 further includes a primary handle or a first handle 524 and an auxiliary handle or a second handle 526. The first handle 524 is coupled to the motor housing portion 518 and disposed rearward of the motor housing portion 518. The first handle 524 is configured to be grasped by a user during operation of the core drill 500. The second handle 526 is removably coupled to the drive housing portion 520. A trigger 528 is provided on the first handle 524 and energizes the motor when depressed by a user. The trigger 528 may be, for example, a variable-speed trigger operable to vary an operating speed of the motor based on an extent to which the trigger 528 is pulled. In other embodiments, the trigger 528 may be an on/off trigger operable to energize the motor to a preset speed. In either case, the trigger 528 has an initial position, in which the motor is de-energized, and a fully-actuated position, in which the motor is operable at a maximum rotational speed for a particular operational setting of the core drill 500.

The core drill 500 also includes a speed selector or electro-mechanical speed switch 552 having an actuator knob 556. The actuator knob 556 is disposed along the drive housing portion 520 and is configured to be rotated by a user to adjust an output speed at which the spindle 530 rotates.

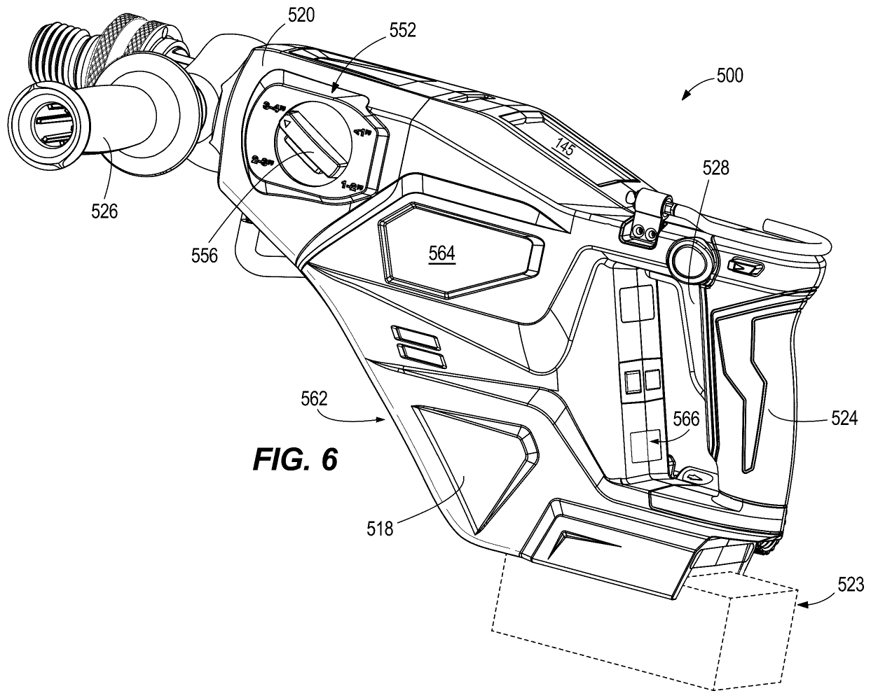

The core drill 500 includes a spindle 530 rotatable about a rotational axis in response to receiving torque from the motor. A tool bit 532 (e.g., a core drilling bit; FIG. 5) can be coupled to a threaded end 531 (see FIG. 6) of the spindle 530 for co-rotation with the spindle 530 to perform work (e.g., core drilling) on a workpiece. In the illustrated embodiment, a locking collar 533 is provided to allow a user to apply a pre-load to the threaded connection between the spindle 530 and the tool bit 532 to secure the tool bit 532. The locking collar 533 may also be actuated to release the pre-load to facilitate removal of the tool bit 532.

Similar to the power tool 100, the core drill 500 includes the controller 300, which is configured to perform the method 400 as described above and control an indicator 145 as described above. The indicator 145 may be positioned at various locations on the core drill 500. For example, as illustrated in FIGS. 5 and 6, the housing 514 (e.g., the motor housing 518) may include a surface including the indicator 145 as described above. The indicator 145 may be positioned on a top surface 560 of the housing 514 and, in particular, may be positioned on a flat or angled top surface of the housing 514. In other embodiments, the indicator 145 may be positioned on a side surface 564 of the housing 514, a front surface 562 of the housing 514, or a rear surface 566 of the housing 514 and, in some embodiments, multiple indicators 145 may be positioned on the tool 500 on one or more surfaces.

It should also be understood that although the indicator 145 is described and illustrated as being included in the power tool (e.g., positioned on a housing of the power tool), in some embodiments, the indicator may be located remote from the power tool and may be provided on a dedicated or general purpose electronic device, such as a user's smart phone, smart wearable (watch), tablet computer, or the like. In this embodiment, the power tool may include a wireless transceiver for communicating with the remote indicator and providing instructions for controlling (e.g., illuminating segments) aspects of the indicator. In some embodiments, the indicator is provided as part of a user interface that can also receive input from a user, such as for using programming, controlling, and/or monitoring the power tool.

Thus, embodiments provided herein describe, among other things, systems and methods for electronically limiting the torque of a power tool. Various features and advantages are set forth in the following claims.

What is claimed is:

1. A power tool comprising:
a housing;
a motor positioned within the housing;
a trigger;
a battery pack interface,
an indicator; and
a controller coupled to the trigger, the motor, the battery pack interface, and the indicator, the controller configured to:
provide power, from a battery pack coupled to the battery pack interface, to the motor based on a displacement of the trigger,
determine a first load level based on at least one selected from a group consisting of a voltage drop of the battery pack and a rotational rate error of the motor,
determine a second load level based on a power calculation, and
output, via the indicator, a load representation based on the first load level and the second load level.

2. The power tool of claim 1, wherein the controller is configured to determine the first load level based on the rotational rate error of the motor, wherein the rotational rate error of the motor includes a revolutions per minute (RPM) error of the motor.

3. The power tool of claim 2, wherein the controller is further configured to determine the RPM error of the motor by subtracting an actual RPM value from a target RPM.

4. The power tool of claim 2, wherein the controller is configured to determine the first load level based on the RPM error of the motor by comparing the RPM error to a plurality of error thresholds, each of the plurality of error thresholds associated with one of a plurality of load levels.

5. The power tool of claim 1, wherein the power calculation is an average power calculation.

6. The power tool of claim 5, wherein the power calculation is based on a current measurement and a voltage measurement.

7. The power tool of claim 6, wherein the current measurement and the voltage measurement are obtained at a printed circuit board of the controller.

8. The power tool of claim 1, wherein the controller is configured to determine the second load level based on the power calculation by comparing the power calculation to a plurality of power thresholds, each of the plurality of power thresholds associated with one of a plurality of load levels.

9. The power tool of claim 1, wherein the controller is configured to output the load representation based on the first load level and the second load level by:
comparing the first load level and the second load level to determine a highest load level, and
outputting the load representation based on the highest load level.

10. The power tool of claim 1, wherein the controller is further configured to determine whether the motor is spinning and, in response to the motor not spinning, not output the load representation.

11. The power tool of claim 1, wherein the indicator includes a display including a plurality of segments, and wherein each segment of the plurality of segments is associated with one of a plurality of load levels.

12. The power tool of claim 11, wherein each of the plurality of segments is transitionable between a first state and a second state, wherein, in the first state, the segment is not illuminated, and wherein, in the second state, the segment is illuminated.

13. The power tool of claim 11, wherein at least one of the plurality of segments is controllable to be illuminated in a color of light selected from a group consisting of red, yellow, and green.

14. The power tool of claim 1, wherein the controller is configured to determine the first load level based on the voltage drop of the battery pack by:
estimating a direct current internal resistance of the battery pack; and
multiplying the direct current internal resistance of the battery pack by a current through the power tool to determine the voltage drop.

15. The power tool of claim 14, wherein the controller is configured to estimate the direct current internal resistance of the battery pack based on a minimum bus voltage, a maximum bus voltage, a minimum bus current, and a maximum bus current determined from a plurality of bus voltage measurements and a plurality of bus current measurements obtained over a period of time.

16. A method of operating a power tool, the method comprising:
providing, with a controller included in the power tool, power from a battery pack coupled to a battery pack interface of the power tool to a motor included in the power tool,
determining, with the controller, a first load level based on at least one selected from a group consisting of a voltage drop of the battery pack and a rotational rate error of the motor,
determining, with the controller, a second load level based on a power calculation, and
outputting, with the controller, a load representation based on the first load level and the second load level via an indicator of the power tool.

17. The method of claim 16, wherein determining the first load level includes determining the first load level based on the rotational rate error of the motor, wherein the rotational rate error of the motor includes a revolutions per minute (RPM) error of the motor.

18. The method of claim 17, wherein determining the first load level based on the RPM error of the motor includes comparing the RPM error to a plurality of error thresholds, each of the plurality of error thresholds associated with one of a plurality of load levels.

19. The method of claim 16, wherein determining the second load level based on the power calculation includes comparing the power calculation to a plurality of power thresholds, each of the plurality of power thresholds associated with one of a plurality of load levels.

20. The method of claim 16, wherein outputting the load representation based on the first load level and the second load level via the indicator of the power tool includes:
comparing the first load level and the second load level to determine a highest load level, and
outputting the load representation based on the highest load level.
